(19) United States
(12) Patent Application Publication
(10) Pub. No.: US 2025/0386570 A1
(43) Pub. Date: Dec. 18, 2025

(54) HIGH ELECTRON MOBILITY TRANSISTOR AND FABRICATION METHOD THEREOF

(71) Applicant: Vanguard International Semiconductor Corporation, Hsinchu (TW)

(72) Inventors: Wei-Chih Cheng, Tainan City (TW); Chia-Hao Lee, Hsinchu County (TW)

(73) Assignee: Vanguard International Semiconductor Corporation, Hsinchu (TW)

(21) Appl. No.: 18/744,680

(22) Filed: Jun. 16, 2024

(51) Int. Cl. H01L 29/10; H01L 21/225; H01L 29/20; H01L 29/66; H01L 29/778

(52) U.S. Cl. CPC H10D 62/393; H01L 21/2258; H10D 30/015; H10D 30/475; H10D 62/8503

(57) ABSTRACT

A high electron mobility transistor includes a channel layer disposed on a substrate and a barrier layer disposed on the channel layer. A cap layer having a conductivity type is disposed on the barrier layer. A gate electrode is disposed on the cap layer. A source electrode and a drain electrode are disposed on the barrier layer and located on two sides of the gate electrode, respectively. In addition, a body region having the same conductivity type as the cap layer is disposed in the barrier layer and the channel layer and located directly below the cap layer.

### BACKGROUND OF THE INVENTION

### 1. Field of the Invention

The present disclosure relates generally to semiconductor technology, and more particularly to enhancement-mode high electron mobility transistors and fabrication methods thereof.

### 2. Description of the Prior Art

In semiconductor technology, group III-V compound semiconductors may be used to construct various integrated circuit devices, such as high-power field-effect transistors, high-frequency transistors, or high electron mobility transistors (HEMTs). A HEMT is a transistor having a two-dimensional electron gas (2DEG) layer close to a junction between two materials with different energy gaps (i.e., a hetero-junction). The 2DEG layer is used as the HEMT channel instead of a doped region, as is generally the case for metal oxide semiconductor field effect transistors (MOSFETs). Compared with MOSFETS, HEMTs have a number of attractive properties, such as high electron mobility and the ability to transmit signals at high frequencies.

HEMTs may be divided into an enhancement-mode (E-mode) HEMT and a depletion-mode (D-mode) HEMT. The E-mode HEMT is a normally off transistor, and its threshold voltage (Vth) is a positive value. The D-mode HEMT is a normally on transistor, and its threshold voltage (Vth) is a negative value. Although the E-mode HEMT is easier to be operated than the D-mode HEMT, the current E-mode HEMTs still cannot fully satisfy the requirements in all aspects of application.

### SUMMARY OF THE INVENTION

In view of this, the present disclosure provides high electron mobility transistors (HEMTs) and fabrication methods thereof. In the HEMTs, a body region is formed in a barrier layer and a channel layer and directly below a cap layer under a gate electrode. The body region and the cap layer have the same conductivity type. The HEMTs have a higher threshold voltage (Vth) through the body region. Moreover, the HEMTs may use a relatively thin cap layer to avoid damage to the barrier layer caused by the patterning process of forming the cap layer, thereby improving the electron mobility and the reliability of the HEMTs.

According to an embodiment of the present disclosure, a high electron mobility transistor is provided and includes a substrate, a channel layer, a barrier layer, a cap layer, a gate electrode, a source electrode, a drain electrode and a body region. The channel layer is disposed on the substrate. The barrier layer is disposed on the channel layer. The cap layer has a conductivity type and is disposed on the barrier layer. The gate electrode is disposed on the cap layer. The source electrode and the drain electrode are disposed on the barrier layer and located on two sides of the gate electrode, respectively. The body region has the same conductivity type as the cap layer. The body region is disposed in the barrier layer and the channel layer, and located directly below the cap layer.

According to an embodiment of the present disclosure, a method of fabricating a high electron mobility transistor is provided and includes the following steps. A substrate is provided and a channel layer is formed on the substrate. A barrier layer is formed on the channel layer. A semiconductor material layer is deposited on the barrier layer. The semiconductor material layer contains a dopant having a conductivity type. The semiconductor material layer is patterned to form a cap layer on the barrier layer. The cap layer contains the aforementioned dopant having the conductivity type. After the cap layer is formed, a heat treatment is performed to form a body region in the barrier layer and the channel layer. The body region contains the aforementioned dopant having the conductivity type and is located directly below the cap layer. A gate electrode is formed on the cap layer. In addition, a source electrode and a drain electrode are formed on the barrier layer and located on two sides of the gate electrode, respectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a high electron mobility transistor (HEMT) according to an embodiment of the present disclosure.

FIG. 2 is a schematic cross-sectional view of a HEMT according to another embodiment of the present disclosure.

FIG. 3, FIG. 4, FIG. 5 and FIG. 6 are schematic cross-sectional views of some stages of a method of fabricating a HEMT according to an embodiment of the present disclosure.

FIG. 7 is a schematic cross-sectional view of an intermediate stage of a method of fabricating a HEMT according to another embodiment of the present disclosure.

FIG. 8 is a schematic cross-sectional view of an intermediate stage of a method of fabricating a HEMT according to further another embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

In the present disclosure, a “compound semiconductor” refers to a group III-V compound semiconductor that includes at least one group III element and at least one group V element, where group III element may be boron (B), aluminum (Al), gallium (Ga) or indium (In), and group V element may be nitrogen (N), phosphorous (P), arsenic (As), or antimony (Sb). Furthermore, the group III-V semiconductor may refer to, but not limited to, gallium nitride (GaN), indium phosphide (InP), aluminum arsenide (AlAs), gallium arsenide (GaAs), aluminum gallium nitride (AlGaN), indium aluminum gallium nitride (InAlGaN), indium gallium nitride (InGaN), aluminum nitride (AlN), gallium indium phosphide (GaInP), AlGaAs, InAlAs, InGaAs, or the like, or the combination thereof. Besides, based on different requirements, group III-V compound semiconductor may contain dopants to become semiconductor with specific conductivity type, such as n-type or p-type.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to an enhancement-mode (E-mode) high electron mobility transistor (HEMT) and a fabrication method thereof. In the E-mode HEMT, a cap layer having a conductivity type is disposed under a gate electrode. A body region is formed in both a barrier layer and a channel layer, and directly below the cap layer through a heat treatment. The body region has the same conductivity type as the cap layer, for example, the cap layer is a p-type compound semiconductor layer, and the body region is a p-type body region. Through the formation of the body region, the HEMT has a higher threshold voltage (Vth). In addition, the HEMT may use a relatively thin cap layer to prevent the surface of the barrier layer from being damaged by an etching process of forming the cap layer, thereby improving the electron mobility and the reliability of the HEMT.

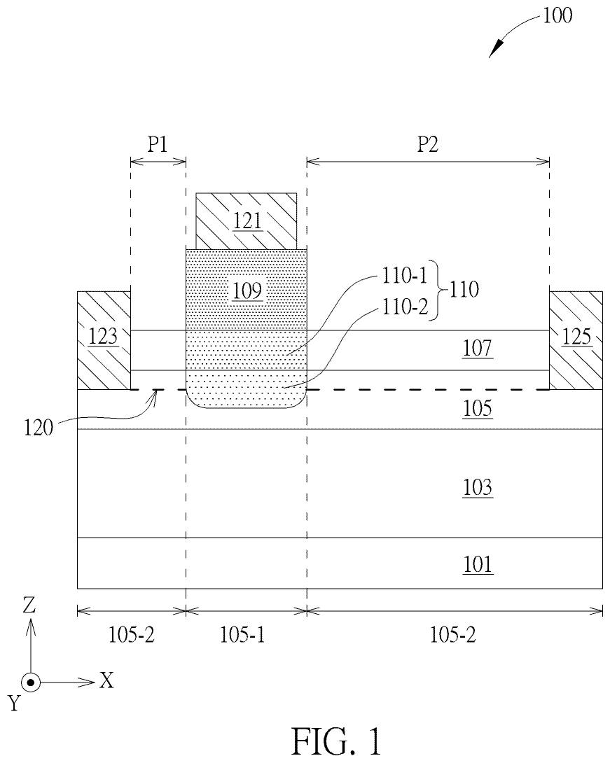

FIG. 1 is a schematic cross-sectional view of a high electron mobility transistor (HEMT) 100 according to an embodiment of the present disclosure. The HEMT 100 includes a substrate 101. In some embodiments, the composition of the substrate 101 may include ceramics, silicon carbide (SiC), aluminum nitride (AlN), sapphire or silicon. When the substrate 101 is made of a material with high hardness, high thermal conductivity and low electrical conductivity, such as a ceramic substrate, it is more suitable for high-voltage semiconductor devices. The aforementioned high hardness, high thermal conductivity and low electrical conductivity are compared with a single-crystal silicon substrate, and the high-voltage semiconductor devices refer to HEMTs with an operating voltage higher than 50V. In n some embodiments, the substrate 101 may be a semiconductor-on-insulator (SOI) substrate. In other embodiments, the substrate 101 may be provided by a composite substrate (or referred to as a QST substrate) composed of a core substrate wrapped around by a composite material layer. The composition of the core substrate includes ceramics, silicon carbide, aluminum nitride, sapphire or silicon. The composite material layer includes an insulating material layer and a semiconductor material layer. The insulating material layer may be a single layer or multiple layers of silicon oxide, silicon nitride or silicon oxynitride. The composition of the semiconductor material layer may be silicon or polysilicon. In addition, during the fabrication of the HEMT, the composite material layer on the backside of the core substrate may be removed by a thinning process, such as a grinding or an etching process, so that the backside of the core substrate is exposed.

In addition, the HEMT 100 may include a buffer structure 103, a channel layer 105 and a barrier layer 107 stacked on the substrate 101 in sequence from bottom to top. In some embodiments, the buffer structure 103 may include a nucleation layer, a buffer layer and a high resistance layer (or referred to as an electrical isolation layer) stacked in sequence from bottom to top. The buffer structure 103 may be used to reduce the degree of stress or lattice mismatch between the substrate 101 and the channel layers 105. The buffer structure 103 may also be referred to as a back-barrier layer. The compositions of the nucleation layer, the buffer layer, the high resistance layer, the channel layer 105 and the barrier layer 107 include compound semiconductors. In some embodiments, the nucleation layer is, for example, an aluminum nitride (AlN) layer. The buffer layer may be a superlattice (SL) structure, for example, including a plurality of alternately stacked aluminum gallium nitride (AlGaN) layers and aluminum nitride (AlN) layers. The high resistance layer is, for example, a carbon-doped gallium nitride (C—GaN) layer. In addition, the channel layer 105 is, for example, an undoped gallium nitride (u-GaN) layer, and the barrier layer 107 is a compound semiconductor layer with an energy gap greater than that of the channel layer 105, such as an aluminum gallium nitride (AlGaN) layer, but not limited thereto. The compositions and the structural configurations of the aforementioned compound semiconductor layers of the HEMT 100 are determined according to various requirements of the HEMT.

Still referring to FIG. 1, the HEMT 100 further includes a cap layer 109 disposed on the barrier layer 107. The cap layer 109 is a compound semiconductor layer with a conductivity type. In some embodiments, the cap layer 109 is, for example, a p-type gallium nitride (p-GaN) layer or a p-type aluminum gallium nitride (p-AlGaN) layer, but not limited thereto. In addition, a gate electrode 121 is disposed on the cap layer 109. A source electrode 123 and a drain electrode 125 are disposed on the barrier layer 107 and located on two opposite sides of the gate electrode 121, respectively. In one embodiment, the source electrode 123 and the drain electrode 125 may penetrate the barrier layer 107 and be extended downward into the channel layer 105. Furthermore, the cap layer 109 and the source electrode 123 are separated by a first distance P1, and the cap layer 109 and the drain electrode 125 are separated by a second distance P2. In one embodiment, the second distance P2 may be greater than the first distance P1, so that the HEMT can withstand a higher operating voltage. In another embodiment, the second distance P2 may be the same as the first distance P1. Moreover, the compositions of the gate electrode 121, the source electrode 123 and the drain electrode 125 may include metals, alloys, metal nitrides or polysilicon. In some embodiments, the metals may include gold (Au), nickel (Ni), platinum (Pt), palladium (Pd), iridium (Ir), titanium (Ti), chromium (Cr), tungsten (W), aluminum (Al), copper (Cu), molybdenum (Mo), other suitable metals, or a combination thereof. The gate electrode 121 may produce a Schottky contact with the cap layer 109. The source electrode 123 and the drain electrode 125 may produce an ohmic contact with the underlying semiconductor layers such as the channel layer 105 and the barrier layer 107.

As shown in FIG. 1, the channel layer 105 and the barrier layer 107 are extended between the source electrode 123 and the drain electrode 125 along the X-axis direction. Since there is a discontinuous energy gap between the channel layer 105 and the barrier layer 107, through stacking the channel layer 105 and the barrier layer 107 with each other, electrons will be gathered at the hetero-junction between the channel layer 105 and the barrier layer 107 due to the piezoelectric effect, thereby producing a thin layer with high electron mobility, i.e., a two-dimensional electron gas (2DEG) region 120. According to some embodiments, the HEMT 100 is an E-mode (or referred to as a normally off) HEMT. When no voltage is applied to the gate electrode 121, a two-dimensional electron gas will not be formed in the area covered by the cap layer 109 (as shown in FIG. 1) and this area is regarded as a 2DEG cut-off region. As a result, there is no conduction between the source electrode 123 and the drain electrode 125. When a positive voltage is applied to the gate electrode 121, a two-dimensional electron gas will be formed in the area covered by the cap layer 109, so that a continuous two-dimensional electron gas region is generated between the source electrode 123 and the drain electrode 125. As a result, the conduction of electricity between the source electrode 123 and the drain electrode 125 is achieved.

According to some embodiments, the HEMT 100 further includes a body region 110 disposed in the barrier layer 107 and the channel layer 105. The body region 110 has the same conductivity type as the cap layer 109. The body region 110 is, for example, a p-body region, and located directly below the cap layer 109. In addition, the top surface of the body region 110 is in direct contact with the bottom surface of the cap layer 109. The body region 110 penetrates the barrier layer 107 and is extended downward into the channel layer 105. The bottom surface of the body region 110 is lower than the top surface of the channel layer 105 and higher than the bottom surface of the channel layer 105. In some embodiments, the bottom surface of the source electrode 123 and the bottom surface of the drain electrode 125 are both located in the channel layer 105, and the bottom surface of the body region 110 may be lower than or higher than the bottom surfaces of the source electrode 123 and the drain electrode 125. Alternatively, the bottom surface of the body region 110 may be level with the bottom surfaces of the source electrode 123 and the drain electrode 125. Moreover, the body region 110 is located directly below the cap layer 109, so that the body region 110 and the source electrode 123 are separated by the first distance P1, and the body region 110 and the drain electrode 125 are separated by the second distance P2. The second distance P2 may be greater than or equal to the first distance P1.

In the conventional HEMTs, in order to have a sufficient threshold voltage (Vth), a thicker cap layer with a thickness of about 70 nm to about 100 nm is usually used. During an etching process of patterning the thicker cap layer, the surface of the barrier layer is damaged by over etching, thereby resulting in poor electron mobility and poor reliability of the conventional HEMTs. According to the embodiments of the present disclosure, the body region 110 is formed in the barrier layer 107 and the channel layer 105 and located directly below the cap layer 109. When no voltage is applied to the gate electrode 121, in addition to the cap layer 109, the body region 110 also contributes to form a 2DEG cut-off region, thereby increasing the threshold voltage (Vth) of the HEMT 100. Compared with the conventional HEMTs without the body region 110, the HEMT 100 of the present disclosure including the body region 110 may use a relatively thin cap layer 109 with a thickness of about 20 nm to about 50 nm, for example, to achieve a higher threshold voltage (Vth). Moreover, during an etching process of patterning the relatively thin cap layer 109, damage to the surface of the barrier layer 107 caused by over-etching is avoided, thereby improving the electron mobility and the reliability of the HEMT 100 of the present disclosure.

According to some embodiments, the cap layer 109 and the body region 110 contain the same dopant with the same conductivity type, such as a p-type dopant. In some embodiments, the p-type dopant includes magnesium (Mg), zinc (Zn), cadmium (Cd) or a combination thereof. In addition, the doping concentration of the p-type dopant such as Mg in the cap layer 109 is higher than the doping concentration of the same p-type dopant in the body region 110. For example, the doping concentration of the p-type dopant of Mg in the cap layer 109 may be about 1E19 to about 5E19 atoms/cm³, and the doping concentration of the p-type dopant of Mg in the body region 110 may be about 1E16 to about 1E19 atoms/cm³, but not limited thereto. The average doping concentration of the p-type dopant in the cap layer 109 is higher than the average doping concentration of the same p-type dopant in the body region 110. Moreover, the doping concentration of the p-type dopant in the body region 110 is gradually decreased in a direction from the cap layer 109 toward the channel layer 105, that is, the doping concentration of the p-type dopant in the body region 110 is gradually decreased downward along the Z-axis direction.

In addition, as shown in FIG. 1, the channel layer 105 includes a first region 105-1 and a second region 105-2. When viewed from a projection direction, the first region 105-1 corresponds to the cap layer 109, and the second region 105-2 corresponds to the area outside the cap layer 109. In one embodiment, the average doping concentration of the p-type dopant in the first region 105-1 of the channel layer 105 is higher than the average doping concentration of the p-type dopant in the second region 105-2. In addition, the body region 110 includes a first portion 110-1 located in the barrier layer 107 and a second portion 110-2 located in the channel layer 105. Except for the p-type dopant, the composition of the first portion 110-1 is the same as that of the barrier layer 107, and the composition of the second portion 110-2 is the same as that of the channel layer 105. For example, the composition of the barrier layer 107 may be aluminum gallium nitride (AlGaN), and the composition of the first portion 110-1 is p-type aluminum gallium nitride (p-AlGaN). The composition of the channel layer 105 may be gallium nitride (GaN), and the composition of the second portion 110-2 is p-type gallium nitride (p-GaN). Moreover, the average doping concentration of the p-type dopant in the first portion 110-1 of the body region 110 is higher than the average doping concentration of the same p-type dopant in the second portion 110-2. In addition, the doping concentrations of the p-type dopant in both the barrier layer 107 and the channel layer 105 are much lower than the doping concentration of the p-type dopant in the body region 110, so that the p-type dopant in the barrier layer 107 and the channel layer 105 may be ignored.

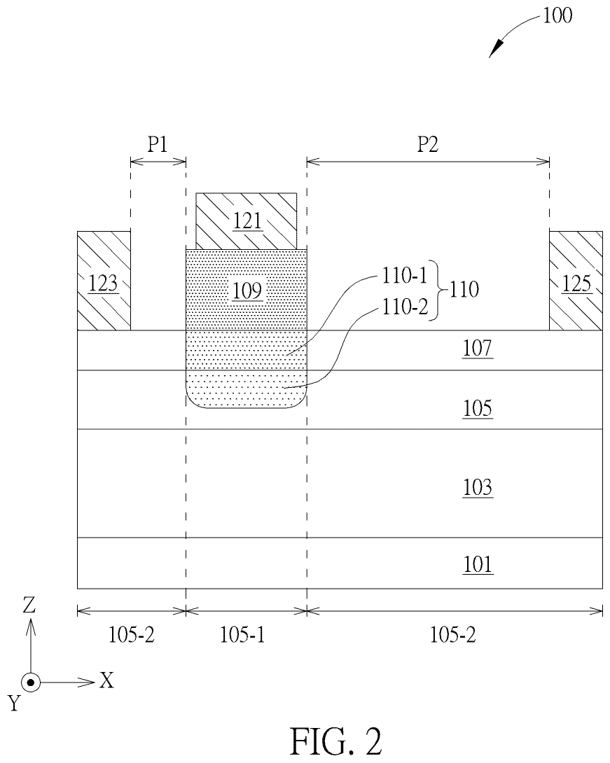

FIG. 2 is a schematic cross-sectional view of a HEMT 100 according to another embodiment of the present disclosure. In the embodiment of FIG. 2, the source electrode 123 and the drain electrode 125 may be disposed on the top surface of the barrier layer 107 without penetrating the barrier layer 107 into the channel layer 105. In other embodiments, the source electrode 123 and the drain electrode 125 may penetrate the barrier layer 107 and be located on the top surface of the channel layer 105. In these embodiments, the body region 110 penetrates the barrier layer 107 and is extended downward into the channel layer 105. The bottom surface of the body region 110 is located in the channel layer 105, and the bottom surface of the body region 110 is much lower than the bottom surfaces of the source electrode 123 and the drain electrode 125. In addition, the details of other features of the HEMT 100 in FIG. 2 may refer to the aforementioned descriptions of the HEMT 100 in FIG. 1, and will not be repeated here.

According to some embodiments of the present disclosure, the bottom surface of the body region 110 is lower than the junction interface between the barrier layer 107 and the channel layer 105, so that the effect of increasing the threshold voltage (Vth) of the HEMT is achieved. Moreover, when the thickness of the cap layer 109 in the HEMT 100 of the present disclosure is the same as the thickness of a cap layer in a conventional HEMT, for example, the thickness of the cap layer 109 is about 50 nm, compared with the conventional HEMT that does not include the body region 110, the Vth of the HEMT of the present disclosure that includes the body region 110 is increased by about 0.3V. In addition, when the thickness of the cap layer 109 is thinner, the effect of increasing the Vth of the HEMT of the present disclosure that includes the body region 110 is more significant than the conventional HEMT. For example, when the thickness of the cap layer 109 is about 30 nm, the Vth of the HEMT of the present disclosure is increased by about 0.5V.

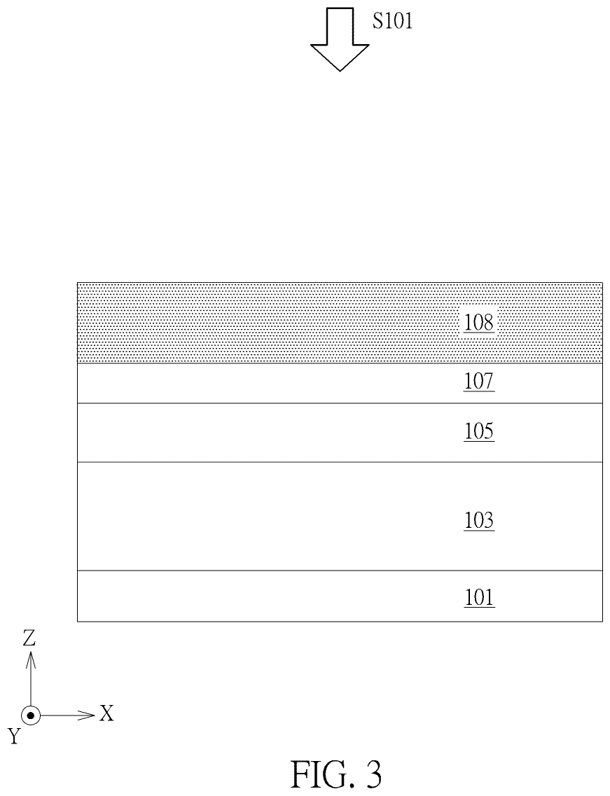

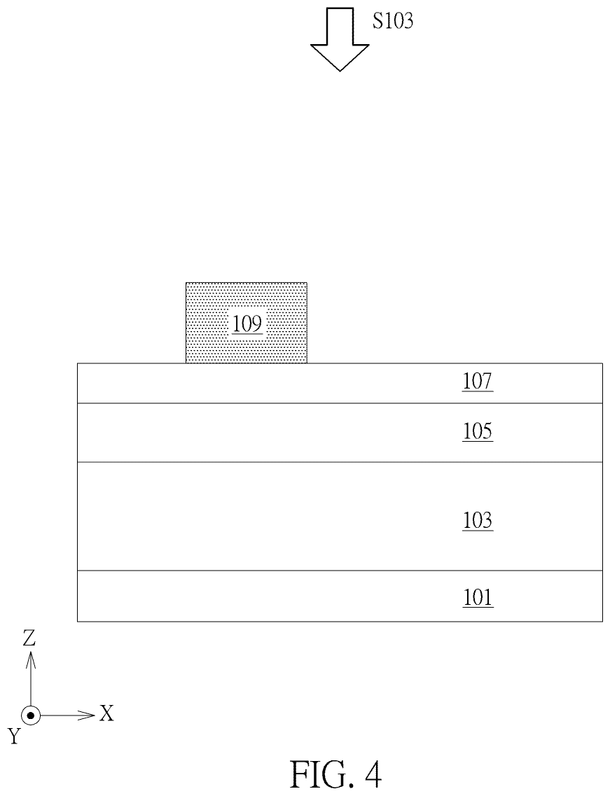

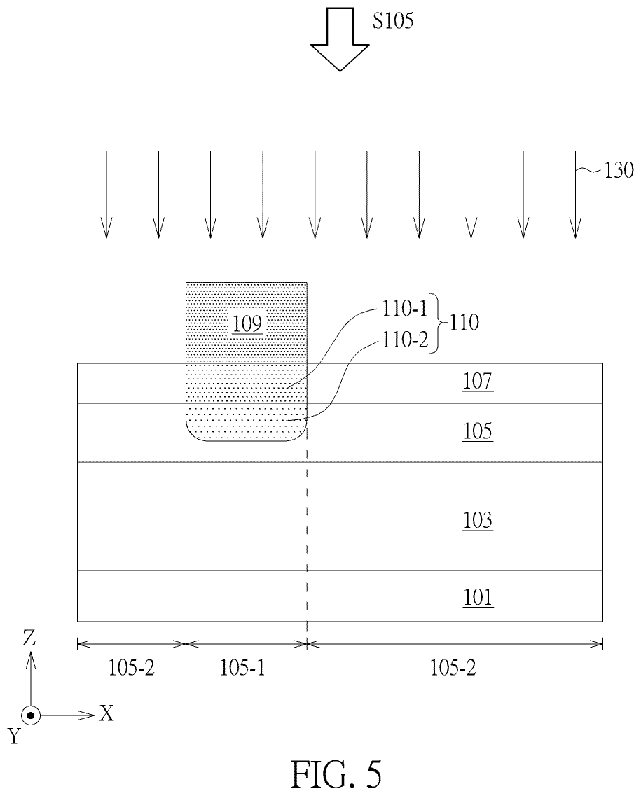

FIG. 3, FIG. 4, FIG. 5 and FIG. 6 are schematic cross-sectional views of some stages of a method of fabricating a HEMT 100 according to an embodiment of the present disclosure. Refer to FIG. 3, in step S101, firstly, a substrate 101 is provided. Then, a buffer structure 103, a channel layer 105 and a barrier layer 107 are formed on the substrate 101 in sequence by using multiple epitaxial growth processes. The compositions of the buffer structure 103, the channel layer 105 and the barrier layer 107 may refer to the aforementioned descriptions of FIG. 1, and will not be repeated here. Next, a semiconductor material layer 108, for example, a p-type gallium nitride (p-GaN) layer is deposited on the barrier layer 107 by using another epitaxial growth process, where a dopant with a conductivity type, such as a p-type dopant of magnesium (Mg), is added during this epitaxial growth process. In some embodiments, the barrier layer 107 has a thickness of about 10 nm to about 15 nm, and the semiconductor material layer 108 has a thickness of about 30 nm to about 100 nm, but not limited thereto.

Then, referring to FIG. 4, in step S103, the semiconductor material layer 108 is patterned by using a patterned mask (not shown) and an etching process, thereby forming a cap layer 109 on the barrier layer 107. The cap layer 109 contains the aforementioned dopant with the conductivity type, such as the p-type dopant of Mg.

Thereafter, referring to FIG. 5, in step S105, after the cap layer 109 is formed, a heat treatment 130 such as an annealing process is performed to allow the p-type dopant in the cap layer 109 to diffuse downward, thereby forming a body region 110 in the barrier layer 107 and the channel layer 105. Moreover, the heat treatment 130 may be performed by using an annealing process in other subsequent steps of fabricating the HEMT without additional process steps. In this embodiment, the body region 110 contains the aforementioned dopant with the conductivity type, such as the p-type dopant of Mg, and the body region 110 is located directly below the cap layer 109. After the heat treatment 130 of step S105 is completed, the doping concentration of the p-type dopant in the cap layer 109 may be slightly lower than the doping concentration of the p-type dopant in the semiconductor material layer 108 of the step S103, and the doping concentration of the p-type dopant in the cap layer 109 is higher than the doping concentration of the p-type dopant in the body region 110. Moreover, the doping concentration of the p-type dopant in the body region 110 is gradually decreased in the direction from the cap layer 109 toward the channel layer 105.

In this embodiment, the body region 110 is formed by thermal diffusion of the p-type dopant in the cap layer 109 into the barrier layer 107 and the channel layer 105. Therefore, a first portion 110-1 of the body region 110 formed in the barrier layer 107 includes the same composition as the barrier layer 107, and a second portion 110-2 of the body region 110 formed in the channel layer 105 includes the same composition as the channel layer 105. Furthermore, the average doping concentration of the p-type dopant in the first portion 110-1 is higher than the average doping concentration of the p-type dopant in the second portion 110-2. In addition, when viewed from a vertical projection direction, the channel layer 105 includes a first region 105-1 corresponding to the cap layer 109, and a second region 105-2 corresponding to the area outside the cap layer 109. After the heat treatment 130 of step S105 is completed, the first region 105-1 may contain a small amount of the p-type dopant, and the second region 105-2 may contain almost no p-type dopant, that is, the doping concentration of the p-type dopant in the first region 105-1 may be higher than the doping concentration of the p-type dopant in the second region 105-2.

In some embodiments, the temperature range of the heat treatment 130 may be from about 800° C. to about 1100° C., and the treatment time of the heat treatment 130 may be from about 20 minutes to about 2 hours, thereby ensuring sufficient thermal diffusion of the p-type dopant to form the body region 110 without damaging other components. In one embodiment, the temperature of the heat treatment 130 may be about 900° C., and the treatment time may be about 1 hour, but not limited thereto. The temperature and the treatment time of the heat treatment 130 may be adjusted according to the doping concentration of the p-type dopant in the cap layer 109 and the predetermined depth of the body region 110. For example, when the doping concentration of the p-type dopant in the cap layer 109 is higher, and/or the predetermined depth of the body region 110 is smaller, the temperature of the heat treatment 130 may be lowered and the treatment time of the heat treatment 130 may be shortened.

Next, referring to FIG. 6, in step S107, a gate electrode 121 is formed on the cap layer 109. In addition, a source electrode 123 and a drain electrode 125 are formed on the barrier layer 107, and located on two opposite sides of the gate electrode 121, respectively. In some embodiments, a dielectric layer (not shown) may be deposited on the cap layer 109 and the barrier layer 107, and then multiple openings for the gate electrode 121, the source electrode 123 and the drain electrode 125 are formed in the dielectric layer, the barrier layer 107 and the channel layer 105 by using a patterned mask and an etching process. Through controlling the etching depths of these openings, the bottom surfaces of the openings for the source electrode 123 and the drain electrode 125 may be located on the top surface of the barrier layer 107, on the top surface of the channel layer 105, or at a depth position in the channel layers 105. In addition, the bottom surface of the opening for the gate electrode 121 may be located on the top surface of the cap layer 109. Thereafter, the aforementioned openings are filled up with a metal material layer by a deposition process, and then the metal material layer is patterned to form the gate electrode 121 on the cap layer 109, and to form the source electrode 123 and the drain electrode 125 on the barrier layer 107, thereby completing the HEMT 100. In one embodiment, as shown in FIG. 1 and FIG. 5, the bottom surfaces of the source electrode 123 and the drain electrode 125 may be located in the channel layer 105. In another embodiment, as shown in FIG. 2, the bottom surfaces of the source electrode 123 and the drain electrode 125 may be located on the top surface of the barrier layer 107. In addition, the compositions of the gate electrode 121, the source electrode 123 and the drain electrode 125 may refer to the aforementioned descriptions of FIG. 1, and will not be repeated here.

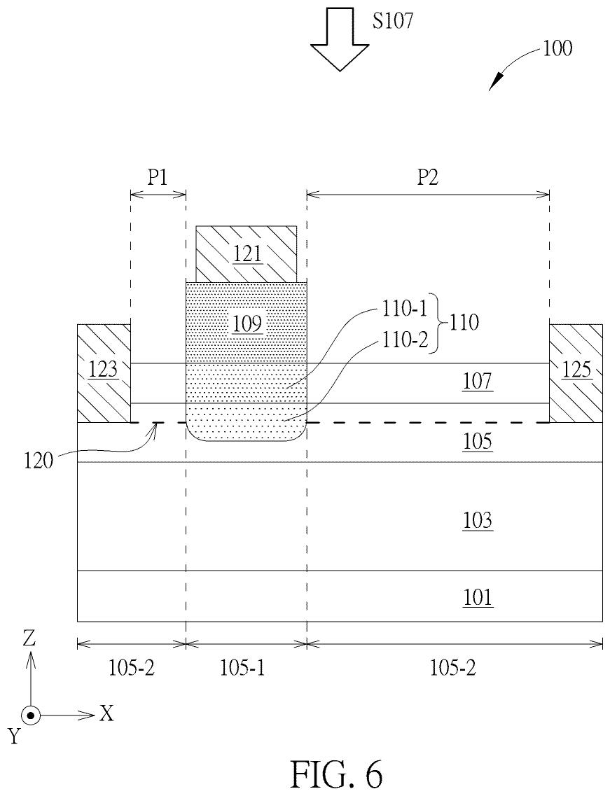

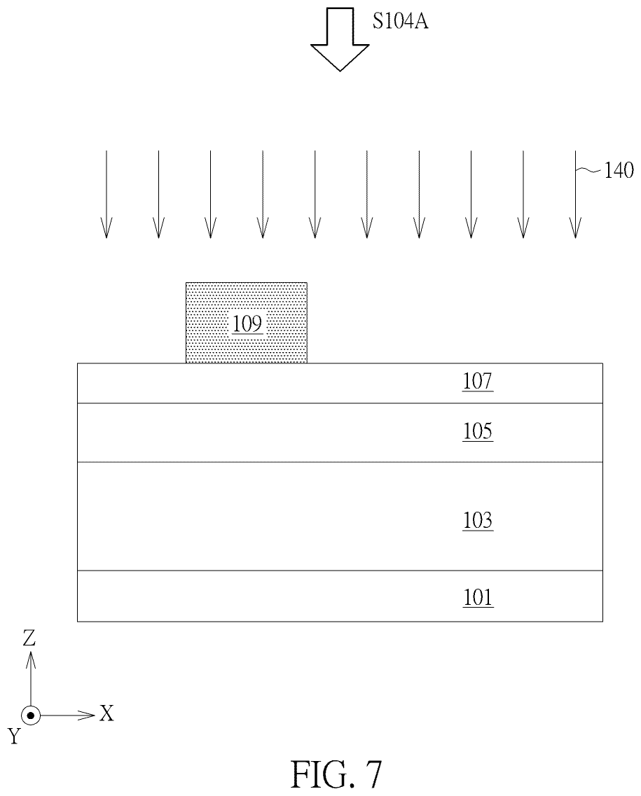

FIG. 7 is a schematic cross-sectional view of an intermediate stage of a method of fabricating a HEMT 100 according to another embodiment of the present disclosure. In this embodiment, after the step S101 in FIG. 3 and the step S103 in FIG. 4 are completed, and before performing the heat treatment 130 of the step S105 in FIG. 5, referring to FIG. 7, in step S104A, a wet etching process 140 is performed on the exposed surface of the cap layer 109 and the exposed surface of the barrier layer 107 to eliminate the defects caused by the etching process of the step 103 on the surfaces of the cap layer 109 and the barrier layer 107, and the surface roughness of the cap layer 109 and the surface roughness of the barrier layer 107 are also reduced. In one embodiment, the wet etching process 140 may use a tetramethyl ammonium hydroxide (TMAH) solution, but not limited thereto. Through the wet etching process 140 of the step S104A, the chemical bonds on the surfaces of the cap layer 109 and the barrier layer 107 are more stable. As a result, during the high-temperature process of the heat treatment 130 in the subsequent step S105, for example, an annealing process of greater than 1000° C., decomposition of the barrier layer 107 and the channel layer 105 is avoided or suppressed, thereby improving the electron mobility and the reliability of the HEMT 100.

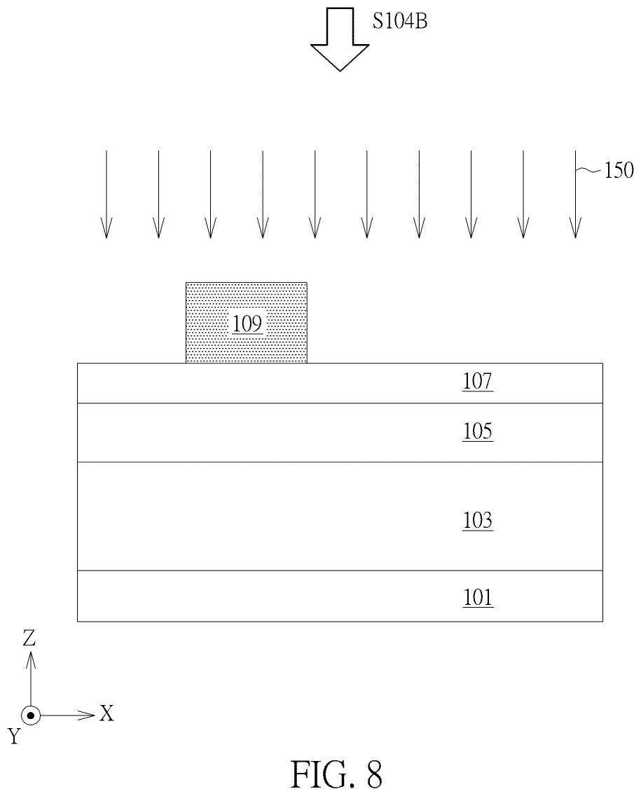

FIG. 8 is a schematic cross-sectional view of an intermediate stage of a method of fabricating a HEMT 100 according to further another embodiment of the present disclosure. In this embodiment, after the step S101 in FIG. 3 and the step S103 in FIG. 4 are completed, and before performing the heat treatment 130 of the step S105 in FIG. 5, referring to FIG. 8, in step S104B, a plasma treatment 150 is performed on the exposed surface of the cap layer 109 and the exposed surface of the barrier layer 107. In one embodiment, the plasma treatment 150 may use an oxygen plasma. The plasma treatment 150 can repair the defects caused by the etching process of the step S103 on the surfaces of the cap layer 109 and the barrier layer 107, so that the chemical bonds on the surfaces of the capping layer 109 and the barrier layer 107 are stronger. As a result, during the high-temperature process of the heat treatment 130 in the subsequent step S105, for example, an annealing process of greater than 1000° C., decomposition of the barrier layer 107 and the channel layer 105 is avoided or suppressed, thereby improving the electron mobility and the reliability of the HEMT 100.

In addition, according to another embodiment of the present disclosure, after the step S101 in FIG. 3 and the step S103 in FIG. 4 are completed, and before performing the heat treatment 130 of the step S105 in FIG. 5, firstly, the wet etching process 140 of the step S104A in FIG. 7 is performed on the exposed surfaces of the cap layer 109 and the barrier layer 107, and then the plasma treatment 150 of the step S104B in FIG. 8 is performed on the exposed surfaces of the cap layer 109 and the barrier layer 107. In this embodiment, through the dual mechanism of the wet etching process 140 and the plasma treatment 150, the etching defects on the surfaces of the cap layer 109 and the barrier layer 107 are repaired better, thereby more effectively improving the electron mobility and the reliability of the HEMT 100.

According to some embodiments of the present disclosure, through the heat treatment, the body region is formed in both the barrier layer and the channel layer and directly below the cap layer. The body region and the cap layer contain the same dopant with the same conductivity type. Through forming the body region, the threshold voltage (Vth) of the E-mode HEMT is increased while a thinner cap layer is used. In addition, the electron mobility and the reliability of the HEMT are improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A high electron mobility transistor, comprising:
a substrate;
a channel layer, disposed on the substrate;
a barrier layer, disposed on the channel layer;
a cap layer, having a conductivity type and disposed on the barrier layer;
a gate electrode, disposed on the cap layer;
a source electrode and a drain electrode, disposed on the barrier layer and located on two sides of the gate electrode, respectively; and
a body region, having the conductivity type the same as that of the cap layer, disposed in the barrier layer and the channel layer, and located directly below the cap layer.

2. The high electron mobility transistor of claim 1, wherein both the cap layer and the body region contain a dopant having the conductivity type, and the dopant comprises a p-type dopant.

3. The high electron mobility transistor of claim 2, wherein a doping concentration of the dopant in the cap layer is higher than a doping concentration of the dopant in the body region.

4. The high electron mobility transistor of claim 2, wherein a doping concentration of the dopant in the body region is gradually decreased in a direction from the cap layer toward the channel layer.

5. The high electron mobility transistor of claim 2, wherein the channel layer comprises a first region corresponding to the cap layer, and a second region corresponding to an area outside the cap layer, and a doping concentration of the dopant in the first region is higher than a doping concentration of the dopant in the second region.

6. The high electron mobility transistor of claim 2, wherein the body region comprises a first portion located in the barrier layer, and a second portion located in the channel layer, the first portion comprises a composition the same as that of the barrier layer, and the second portion comprises a composition the same as that of the channel layer.

7. The high electron mobility transistor of claim 6, wherein a doping concentration of the dopant in the first portion is higher than a doping concentration of the dopant in the second portion.

8. The high electron mobility transistor of claim 1, wherein a top surface of the body region is in direct contact with a bottom surface of the cap layer.

9. The high electron mobility transistor of claim 1, wherein the body region penetrates the barrier layer, a bottom surface of the body region is lower than a top surface of the channel layer and higher than a bottom surface of the channel layer.

10. The high electron mobility transistor of claim 1, wherein a bottom surface of the source electrode and a bottom surface of the drain electrode are both located in the channel layer, and a bottom surface of the body region is higher or lower than both the bottom surface of the source electrode and the bottom surface of the drain electrode.

11. The high electron mobility transistor of claim 1, wherein the body region and the source electrode are separated by a first distance, the body region and the drain electrode are separated by a second distance, and the second distance is greater than the first distance.

12. A method of fabricating a high electron mobility transistor, comprising:
provide a substrate;
forming a channel layer on the substrate;
forming a barrier layer on the channel layer;
depositing a semiconductor material layer on the barrier layer, wherein the semiconductor material layer contains a dopant having a conductivity type;
patterning the semiconductor material layer to form a cap layer on the barrier layer, wherein the cap layer contains the dopant having the conductivity type;
performing a heat treatment to form a body region in the barrier layer and the channel layer after the cap layer is formed, wherein the body region contains the dopant having the conductivity type, and the body region is located directly below the cap layer;
forming a gate electrode on the cap layer; and
forming a source electrode and a drain electrode on the barrier layer and located on two sides of the gate electrode, respectively.

13. The method of claim 12, wherein a doping concentration of the dopant in the cap layer is higher than a doping concentration of the dopant in the body region, and the dopant comprises a P-type dopant.

14. The method of claim 12, wherein the dopant diffuses from the cap layer into the barrier layer and the channel layer through the heat treatment, and a doping concentration of the dopant in the body region is gradually decreased in a direction from the cap layer toward the channel layer.

15. The method of claim 12, wherein the body region comprises a first portion formed in the barrier layer, and a second portion formed in the channel layer, the first portion comprises a composition the same as that of the barrier layer, the second portion comprises a composition the same as that of the channel layer, and a doping concentration of the dopant in the first portion is higher than a doping concentration of the dopant in the second portion.

16. The method of claim 12, wherein the channel layer comprises a first region corresponding to the cap layer, and a second region corresponding to an area outside the cap layer, and a doping concentration of the dopant in the first region is higher than a doping concentration of the dopant in the second region.

17. The method of claim 12, further comprising performing a wet etching process on an exposed surface of the cap layer and an exposed surface of the barrier layer after the cap layer is formed and before performing the heat treatment, wherein the wet etching process comprises using a tetramethyl ammonium hydroxide solution.

18. The method of claim 12, further comprising performing a plasma treatment on an exposed surface of the cap layer and an exposed surface of the barrier layer after the cap layer is formed and before performing the heat treatment, wherein the plasma treatment comprises using an oxygen plasma.

19. The method of claim 12, further comprising performing a wet etching process and a plasma treatment on an exposed surface of the cap layer and an exposed surface of the barrier layer after the cap layer is formed and before performing the heat treatment, wherein the plasma treatment is performed after the wet etching process.

20. The method of claim 12, wherein the heat treatment has a temperature range of 800° C. to 1100° C., and a treatment time of 20 minutes to 2 hours.
